(19) United States
(12) Patent Application Publication
(10) Pub. No.: US 2008/0187871 A1
(43) Pub. Date: Aug. 7, 2008

(54) PATTERN FORMING APPARATUS AND METHOD

(75) Inventors: Takashi FUKUI, KANAGAWA (JP); Kazuhiro TERADA, KANAGAWA (JP); Yuji SHIMOYAMA, KANAGAWA (JP); Hiroshi SHIBATA, KANAGAWA (JP); Hiroshi UEMURA, KANAGAWA (JP)

Correspondence Address: YOUNG & THOMPSON, 209 Madison Street, Suite 500, ALEXANDRIA, VA, 22314, US

(73) Assignee: FUJIFILM CORPORATION, TOKYO (JP)

(21) Appl. No.: 11/970,542

(22) Filed: Jan. 8, 2008

(30) Foreign Application Priority Data
Feb. 2, 2007 (JP) 2007-023961
Feb. 2, 2007 (JP) 2007-023962

(51) Int. Cl. G03F 7/20; G03B 27/42

(52) U.S. Cl. 430/322; 355/53

(57) ABSTRACT

A pattern forming apparatus as exposure apparatus includes first and second movable stages for respectively supporting first and second boards placed thereon, and for transporting each board back and forth on a transport path. A pattern forming unit with DMD and laser forms a pattern on the board according to pattern data while the board moves into and out of a pattern forming region. A controller controls the pattern forming unit, and in a first period, moves a first board in a first direction on the transport path among plural boards, to form the pattern, and in a second period, moves a second board in the first direction on the transport path among the plural boards, to form the pattern. The pattern forming unit is disposed in a middle of the transport path, and is passed by the movable stages, for pattern forming selectively on the first and second boards.

### BACKGROUND OF THE INVENTION

1. Field of the Invention

The present invention relates to a pattern forming apparatus and method. More particularly, the present invention relates to a pattern forming apparatus and method in which a pattern is formed on a surface of a board, and of which a structure can be simplified at the same with high productivity.

2. Description Related to the Prior Art

A digital exposure apparatus is a pattern forming apparatus having a pattern forming unit. A group of spacial light modulators, such as a DMD (digital micro mirror device), are incorporated in the pattern forming unit, and are driven according to pattern data to modulate a light beam. Pattern forming is carried out on the board by exposure. The digital exposure apparatus is referred to also as a multi-beam exposure apparatus. The DMD is a mirror device including a SRAM cells or memory cells, and micro mirrors. The SRAM cells are arranged on a semiconductor substrate in a two dimensional manner. The micro mirrors are secured to the memory cells in a pivotally movable manner. Data is written to respectively the memory cells as static charge. An angle of a reflection surface of the micro mirrors is changed according to the electrostatic force.

A suggested example of the digital exposure apparatus has the pattern forming unit which extends higher than and crosswise to an exposure surface of a board in reference direction. A board is moved relative to the pattern forming unit crosswise to the reference direction. Data for driving the spacial light modulators in the pattern forming unit are changed according to the moving of the board. An image is formed on the entirety of the exposure surface. The pattern forming is possible in the digital exposure apparatus for a board of a large size, for example a printed circuit board, a glass board for a flat panel display. However, there is a problem in a long takt time required for each one of boards, to result in a low productivity.

JP-A 2005-037914 discloses the digital exposure apparatus having two movable stages which start from a loading position, pass the pattern forming unit, and move to a removing position for the purpose of high productivity. In a first one of the movable stages, the pattern forming for a board is carried out, while a second one of the movable stages is loaded with a new board by exchange. Also, a board on the second stage is measured for the alignment.

In the digital exposure apparatus of JP-A 2005-037914, a loading position for a board is equal between the movable stages. A first one of the movable stages passes by on a transport path with a second one of them in moving from the removing position to the loading position after completing the pattern forming. A first one of the movable stages is disposed separate from a second one of the movable stages in a vertical direction to prevent interference between those. There is a problem of complexity of the digital exposure apparatus in JP-A 2005-037914 due to requirement of a structure for preventing interference between the movable stages on the transport path.

### SUMMARY OF THE INVENTION

In view of the foregoing problems, an object of the present invention is to provide a pattern forming apparatus and method in which a pattern is formed on a surface of a board, and of which a structure can be simplified at the same with high productivity.

In order to achieve the above and other objects and advantages of this invention, a pattern forming apparatus includes a pattern forming unit for sequentially forming a pattern on a board passing a pattern forming region according to pattern data. A moving unit has a transport path extending to pass the pattern forming region for the board, for transporting first and second boards back and forth in a first direction relative to the pattern forming region and a second direction reverse to the first direction in an alternate manner, the first board being set at one end of a transport path, the second board being set at a remaining end of the transport path. A controller controls the pattern forming unit and the moving unit, forms the pattern on the first board in a first period of transport in the first direction to pass the pattern forming region, and forms the pattern on the second board in a second period of transport in the first direction to pass the pattern forming region.

The moving unit includes first and second movable stages for respectively supporting the first and second boards placed thereon. A guide mechanism movably guides the first and second movable stages on the transport path. A moving mechanism moves the first and second movable stages discretely from one another on the transport path.

Furthermore, a board position detector detects a position offset value of the board with reference to a suitable position. A pattern data corrector corrects the pattern data according to the position offset value from the board position detector.

The moving unit, during or after the first period, moves the second board toward the pattern forming unit in the first direction, to measure the second board in the board position detector. The moving unit, during or after the second period, moves the first board toward the pattern forming unit in the second direction, to measure the first board in the board position detector.

Furthermore, first and second board exchangers disposed at the ends of the transport path, the first board exchanger renewing the first board in the second period, and the second board exchanger renewing the second board in the first period.

A set of the first and second board exchangers includes a conveyor, disposed to extend along the transport path, for setting the board near to the first movable stage at the one end of the transport path and near to the second movable stage at the remaining end of the transport path. First and second shifters hold the board from the conveyor and place the board on respectively the first and second movable stages.

Furthermore, there are first and second prealignment adjusters for position adjustment of the board by supporting the board from the first and second shifters.

The second prealignment adjuster has a turntable for changing an orientation of the board rotationally by a half rotation.

Furthermore, an angle adjuster adjusts an angle of the board relative to the transport path, to orient the board in a predetermined direction.

Furthermore, a pattern data setter sets the pattern data in a different manner between the first and second periods.

The board is photosensitive. The pattern forming unit includes a light source for emitting light. A light valve modulates the light according to the pattern data, and exposes the pattern by applying the light to the board.

The light valve is constituted by plural light valves, the pattern forming unit is a multi-beam type, and the light is laser light.

Preferably, the light valve includes a spatial light modulator.

Before the first period, the first movable stage moves the first board in a second direction reverse to the first direction by passing the pattern forming unit, and then in the first period, moves back the first board in the first direction by passing the pattern forming unit for pattern forming. In the second period, the second movable stage moves the second board in the first direction by passing the pattern forming unit for pattern forming, and then moves back the second board in the second direction by passing the pattern forming unit.

The transport path includes a first end area having a size for containing the first movable stage. A second end area has a size for containing the second movable stage. A passage area includes the pattern forming region, disposed to extend between the first and second end areas, for keeping the first and second movable stages passable, the passage area having a form in which the first movable stage is containable between the second end area and the pattern forming region and in which the second movable stage is containable between the first end area and the pattern forming region.

In one aspect of the invention, a pattern forming method of forming a pattern on a moving board according to pattern data is provided. The pattern forming method includes setting a first board at one end of a transport path and a second board at a remaining end of the transport path which extends to pass a pattern forming region, the first and second boards being movable back and forth in a first direction relative to the pattern forming region and a second direction reverse to the first direction in an alternate manner. The pattern is formed on the first board in a first period of transport in the first direction to pass the pattern forming region. The pattern is formed on the second board in a second period of transport in the first direction to pass the pattern forming region.

In another aspect of the invention, a pattern forming apparatus includes a pattern forming unit for sequentially forming a pattern on a board passing a pattern forming region according to pattern data. A moving unit has a transport path extending to pass the pattern forming region for the board, for transporting first and second boards back and forth in a first direction relative to the pattern forming region and a second direction reverse to the first direction in an alternate manner, the first board being set at one end of a transport path, the second board being set at a remaining end of the transport path. A controller controls the pattern forming unit and the moving unit, forms the pattern on the first board in a first period of transport in the first direction to pass the pattern forming region, and forms the pattern on the second board in a second period of transport in the second direction to pass the pattern forming region. A pattern data setter sets the pattern data different between the first and second periods.

The pattern data setter sets the pattern data in a different manner between the first and second periods so as to form the pattern being equal on the boards in the first and second periods.

While the pattern forming unit carries out the pattern forming on the first board among the plural boards, the board position detector detects the position offset value of the second board among the plural boards.

Before the first period, the first movable stage moves the first board in the second direction by passing the pattern forming unit, and then in the first period, moves back the first board in the first direction by passing the pattern forming unit for pattern forming. Before the second period, the second movable stage moves the second board in the first direction by passing the pattern forming unit, and then in the second period, moves back the second board in the second direction by passing the pattern forming unit for pattern forming.

Also, a computer executable program for pattern forming is provided, and includes a program code for transporting a board back and forth on a transport path, to move into and out of a pattern forming region. A program code is for forming a pattern on the board according to pattern data while the board passes the pattern forming region. A program code is for, in a first period, moving a first board in a first direction on the transport path among plural boards, for pattern forming. A program code is for, in a second period, moving a second board in the first direction on the transport path among the plural boards, for pattern forming.

Accordingly, a structure of the apparatus can be simplified at the same with high productivity, because the first and second periods are determined for alternate transport of plural boards in one transport path.

### BRIEF DESCRIPTION OF THE DRAWINGS

The above objects and advantages of the present invention will become more apparent from the following detailed description when read in connection with the accompanying drawings, in which:

FIG. 1 is a perspective view illustrating a digital exposure apparatus as pattern forming apparatus;

FIG. 2 is an explanatory view in elevation illustrating a pattern forming unit as exposure head;

FIG. 3 is a perspective view illustrating DMD;

FIG. 4 is a perspective view illustrating pattern forming regions on a board;

FIG. 5 is a block diagram schematically illustrating the digital exposure apparatus;

FIG. 6 is an explanatory view in plan illustrating a digital exposure system including the digital exposure apparatus;

FIGS. 7A, 7B and 7C are explanatory views in plan illustrating a first portion of a sequence of operation of the digital exposure apparatus;

FIGS. 8A, 8B and 8C are explanatory views in plan illustrating a second portion of the sequence of operation of the digital exposure apparatus;

FIG. 9 is an explanatory view in plan illustrating a third portion of the sequence of operation of the digital exposure apparatus;

FIG. 10 is a timing chart illustrating the sequence;

FIG. 11 is a block diagram schematically illustrating another preferred digital exposure apparatus;

FIG. 12 is an explanatory view in plan illustrating still another preferred digital exposure apparatus;

FIGS. 13A, 13B and 13C are explanatory views in plan illustrating a first portion of a sequence of operation of the digital exposure apparatus;

FIGS. 14A, 14B and 14C are explanatory views in plan illustrating a second portion of the sequence of operation of the digital exposure apparatus;

FIGS. 15A, 15B and 15C are explanatory views in plan illustrating a third portion of the sequence of operation of the digital exposure apparatus;

FIG. 16 is a timing chart illustrating the sequence.

### DETAILED DESCRIPTION OF THE PREFERRED EMBODIMENT(S) OF THE PRESENT INVENTION

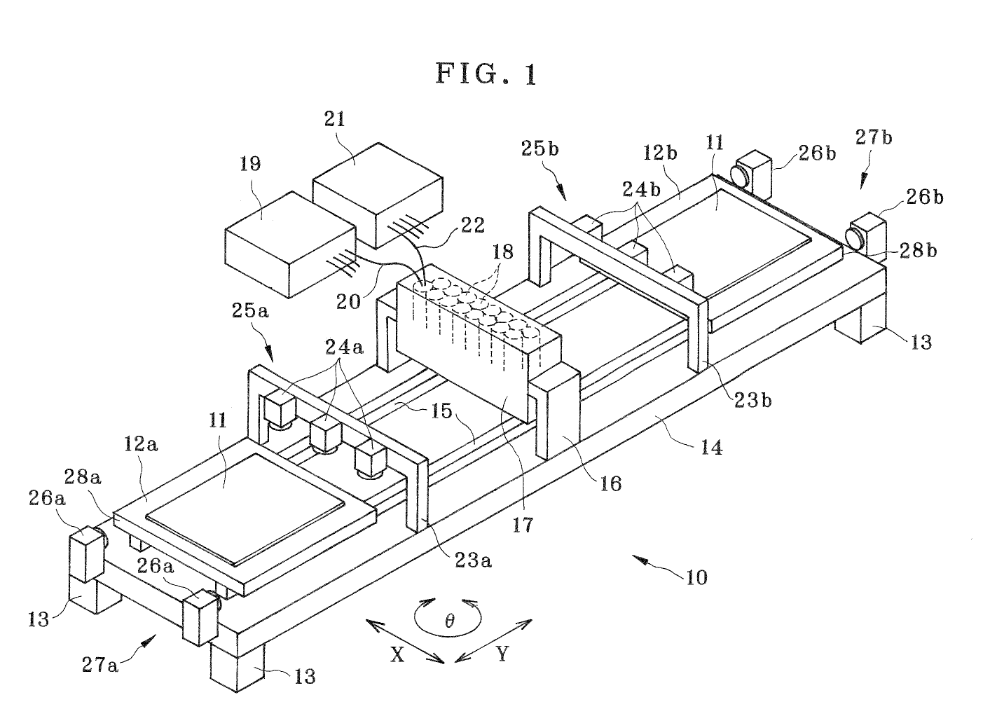

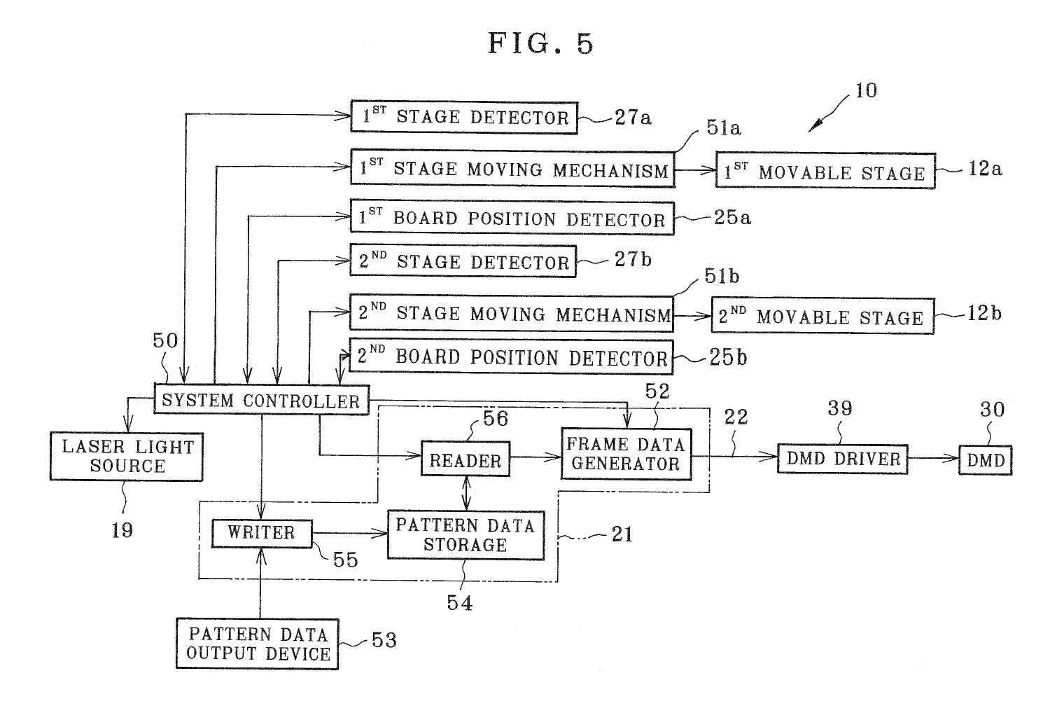

In FIG. 1, a digital exposure apparatus 10 for pattern forming includes first and second movable stages or pallets 12a and 12b. A board or substrate 11 for pattern forming is placed on and kept positioned on the first and second movable stages 12a and 12b by suction or the like. Examples of the board 11 are a printed circuit board, glass substrate for a flat panel display, and the like. A layer of photosensitive material is positioned on a surface of the board 11 by application of coating or adhesion. A base panel 14 is included in the digital exposure apparatus 10. Four legs 13 support corners of the base panel 14. Two guide rails 15 or transport path are disposed to extend in the direction Y on the base panel 14. The first and second movable stages 12a and 12b are supported by the guide rails 15 on a transport path or one dimensional orbit. A first stage moving mechanism 51a and a second stage moving mechanism 51b of FIG. 5, each of which includes a linear motor, drive respectively the first and second movable stages 12a and 12b.

A gate 16 is disposed at the center of the base panel 14 and extends higher than and crosswise to the guide rails 15. A multi-beam pattern forming unit 17 by exposure is supported on the gate 16. 16 light valves or exposure heads 18 are included in the pattern forming unit 17, are stationary, and are arranged in two valve arrays extending crosswise to the path of the first and second movable stages 12a and 12b.

An optical fiber 20 and a connection cable 22 are connected with the pattern forming unit 17 of exposure. A laser light source 19 is connected by the optical fiber 20 to the pattern forming unit 17. An image processor 21 is connected by the connection cable 22 to the pattern forming unit 17. Frame data is output by the image processor 21 to cause the exposure heads 18 to modulate light beam from the laser light source 19. An exposure is taken on the board 11 transported by each of the first and second movable stages 12a and 12b to form a pattern. Note that the number and arrangement of the exposure heads 18 can be changed according to the size or the like of the board 11.

Two gates 23a and 23b are disposed higher than and crosswise to the guide rails 15 or transport path, and symmetric to one another with respect to the gate 16 on the base panel 14. Three image sensors or cameras 24a are supported on the gate 23a on the side of the first movable stage 12a. The image sensors 24a are stationary over the path of the first movable stage 12a. A first board position detector 25a includes the image sensors 24a and measures the position of the board 11 on the first movable stage 12a for measurement of alignment. Also, three image sensors or cameras 24b are supported on the gate 23b on the side of the second movable stage 12b. The image sensors 24b are stationary over the path of the second movable stage 12b. A second board position detector 25b includes the image sensors 24b, and measures the position of the board 11 on the second movable stage 12b for measurement of alignment. The board position detectors 25a and 25b read an indicia, pattern and the like from the board 11, and detect offset values of the directions X, Y and θ with reference to the suitable position on the first and second movable stages 12a and 12b. The detected values are used for correcting frame data. Note that the number of the image sensors 24a and 24b is changeable according to the size of the board 11.

Length measurers 26a and 26b of a laser interference type are disposed at ends of the base panel 14 as viewed in the direction Y. A first stage detector 27a is constituted by the length measurers 26a, which are two arranged in the direction X on the side of the first movable stage 12a at a first end of the base panel 14. A second stage detector 27b is constituted by the length measurers 26b, which are two arranged in the direction X on the side of the second movable stage 12b at a second end of the base panel 14. A stage end face 28a of the first movable stage 12a and a stage end face 28b of the second movable stage 12b receive application of laser light from the first and second stage detectors 27a and 27b, and are detected for their position in the direction Y. Values of the detection are used for correction of the first and second movable stages 12a and 12b.

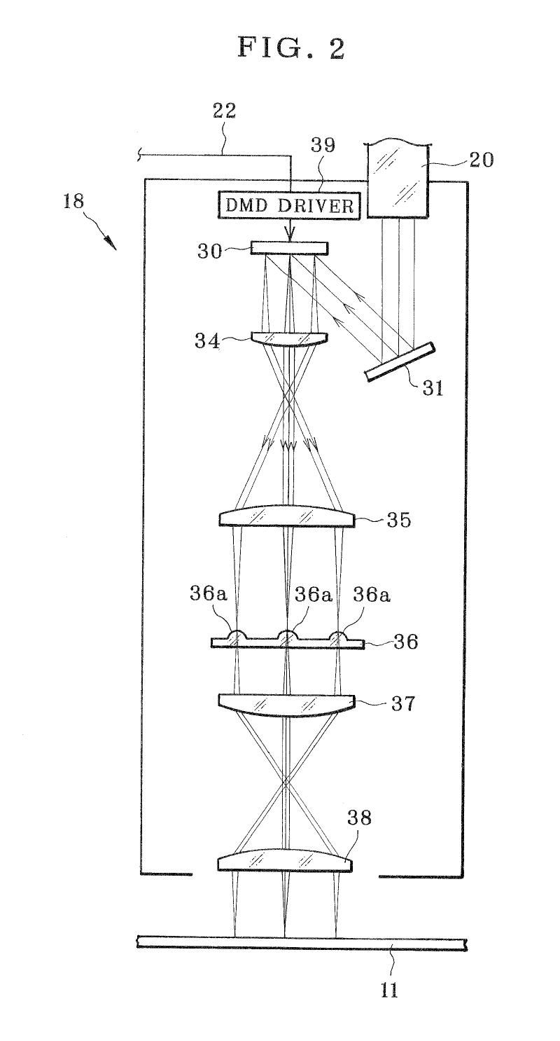

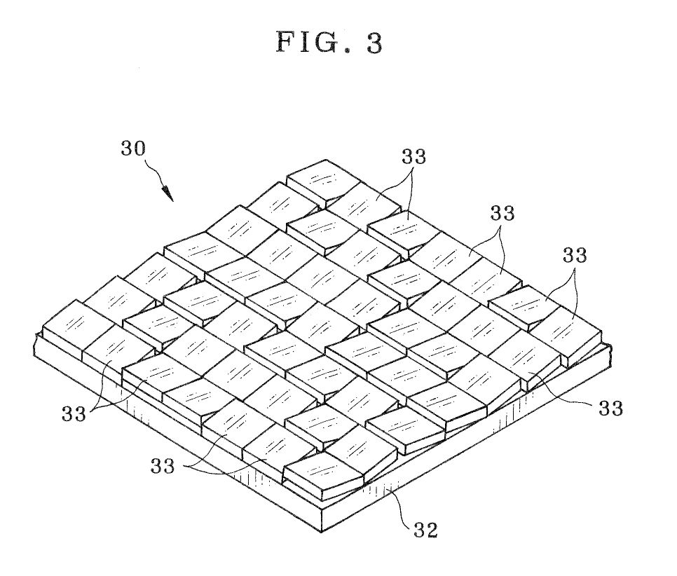

In FIG. 2, elements in the light valves or exposure heads 18 are illustrated. A DMD (digital micro mirror device) 30 is included in the exposure heads 18 as spacial light modulator. A reflector 31 is disposed upstream from the DMD 30, and reflects light emitted from an end of the optical fiber 20 toward the DMD 30. In FIG. 3, an SRAM cell array 32 is illustrated. Micro mirrors 33 are supported by posts on respectively cells of the SRAM cell array 32 in a pivotally movable manner. The micro mirrors 33 are arranged in a matrix of a two dimensional rectangular form of 600×800 cells. A shape of the DMD 30 is rectangular. A DMD driver 39 is used to write frame data of a digital signal to the SRAM cell array 32. The connection cable 22 is connected with the DMD driver 39, to input the frame data from the image processor 21.

Cells of the SRAM cell array 32 are flip-flop circuits, of which a charged state is changed according to written data of 0 or 1. The micro mirrors 33 are controlled to change their tilt angle by electrostatic force according to the charged state of the SRAM cells, so that the micro mirrors 33 change a direction of reflection of laser light traveling from the reflector 31. Lens optics 34 receive reflected light modulated and reflected by the DMD 30 according to the frame data. Only reflection light from the micro mirrors 33 in the SRAM cells with the written data of 0 becomes incident upon the lens optics 34. However, reflection light from the micro mirrors 33 in the SRAM cells with the written data of 1 does not become incident, but is absorbed by light absorbing material (not shown), and does not cause an exposure.

Lens optics 35 are combined with the lens optics 34 as enlarging lens group, which enlarges an area of a section of the reflected light from the DMD 30 in a predetermined size. A micro lens array 36 is disposed on the exit side of the lens optics 35, and receives entry of the reflected light with an enlarged area. Plural micro lenses 36a are included in the micro lens array 36, and respectively correspond to the micro mirrors 33 of the DMD 30 one by one. Each of the micro lenses 36a is disposed on an optical axis of laser light passed through the lens optics 34 and 35. Lens optics 37 receive entry of the image light of the enlarged size after sharpening in the micro lens array 36. Lens optics 38 are combined with the lens optics 37 as lens group of an equal magnification, which projects an image to the board 11 for exposure. The exposure heads 18 are disposed to position an exposure surface of the board 11 in a rear focal point of the lens optics 37 and 38.

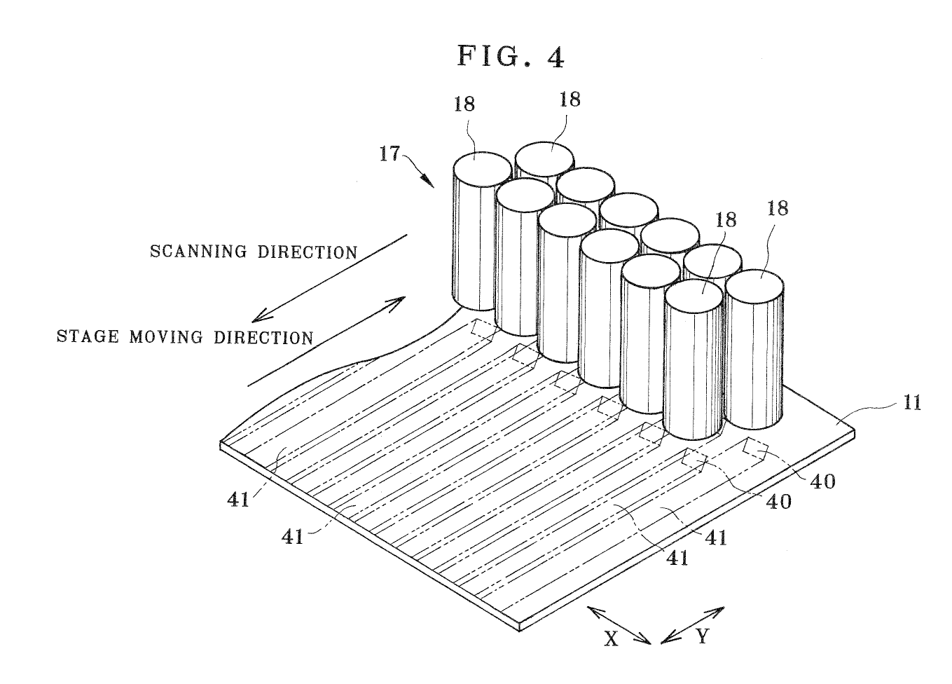

In FIG. 4, pattern forming regions 40 of exposure on the board 11 after the use of the light valves or exposure heads 18 are in a form of a rectangular quadrilateral which is similar to the DMD 30. The DMD 30 is so oriented that its shorter side is tilted at a small angle of 0.1-0.5 degree with respect to the direction Y. Therefore, the pattern forming regions 40 are tilted. A direction of arrangement of exposure point in a matrix form by use of the micro mirrors 33 of the DMD 30 is tilted relative to the scanning direction. A pitch of the scanning line with the exposure points as viewed in the direction X is small. Thus, it is possible to keep high the resolving power over a structure without a tilt of the DMD 30.

The two arrays of the light valves or exposure heads 18 extend in the direction X which is crosswise to the transport path. The exposure heads 18 are arranged in contact with one another without gaps. The exposure heads 18 of a first array are offset from those of the second array by a regular interval of half of the pitch. A portion unrecorded even after the use of the first array can be exposed by the second array of the exposure heads 18. Exposed regions 41 of a strip shape are formed to extend without a gap if viewed in the direction X.

In FIG. 5, circuit elements of the digital exposure apparatus 10 are illustrated. A system controller 50 is incorporated to control various circuits in the digital exposure apparatus 10. The first stage moving mechanism 51a for the first movable stage 12a, and the second stage moving mechanism 51b for the second movable stage 12b are driven by the system controller 50 for moving. Also, the system controller 50 controls the laser light source 19 and the image processor 21 to take an exposure. Also, the first and second stage detectors 27a and 27b are monitored by the system controller 50, and output detection values according to which the system controller 50 corrects the stage positions by feedback of the stage moving mechanisms 51a and 51b. The board position detectors 25a and 25b are monitored by the system controller 50. A frame data generator 52 in the image processor 21 is supplied by the system controller 50 with the detection values of the board positions, so that the frame data is corrected.

A pattern data storage 54 is incorporated in the image processor 21. A pattern data output device 53 may be externally connected with the digital exposure apparatus 10, outputs pattern data of a rasterized form, which is written to the pattern data storage 54. A writer 55 is connected with the pattern data storage 54 for control of writing. A reader 56 is connected with the pattern data storage 54 for control of reading. The writer 55 writes pattern data from the pattern data output device 53 to the pattern data storage 54. The reader 56 is controlled by the system controller 50, and reads pattern data from the pattern data storage 54 and sends the pattern data to the frame data generator 52.

The frame data generator 52 generates frame data according to the image data being input, and sends the frame data to the DMD driver 39. Specifically, the frame data generator 52 generates the frame data according to the coordinates of the exposure points in the pattern forming regions 40 determined by the arrangement of the micro mirrors 33 of the DMD 30 and the arrangement of the light valves or exposure heads 18. Also, the frame data generator 52 corrects the frame data according to the offset value of the position of the board 11 detected by the board position detectors 25a and 25b so as to form exposure points at the same points as in a state without the shift of the position.

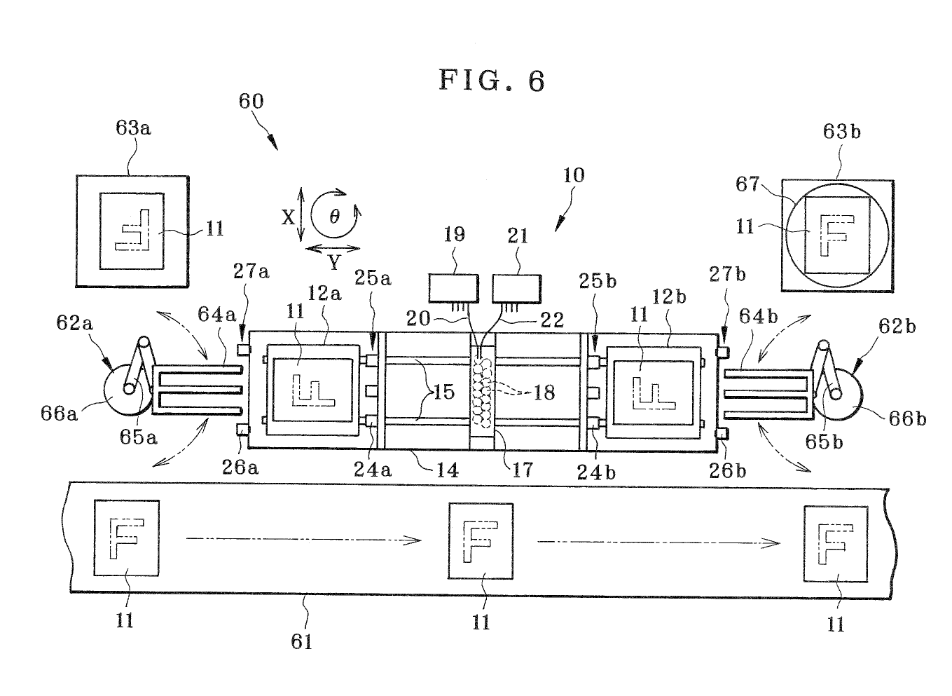

In FIG. 6, a digital exposure system 60 for pattern forming is illustrated in which a loading mechanism for the board 11 is added to the digital exposure apparatus 10. The digital exposure system 60 includes a conveyor 61, board exchangers 62a and 62b with transport robots or shifters, and first and second prealignment adjusters 63a and 63b with a stage. A controller (not shown) controls those elements.

The conveyor 61 is disposed to extend along a longer side of the base panel 14 of the digital exposure apparatus 10. The board exchangers 62a and 62b are opposed to shorter sides of the base panel 14. The conveyor 61 transports a plurality of the boards 11 at a regular interval in a direction from the first movable stage 12a toward the second movable stage 12b. An example of a pattern for forming is a letter F for the purpose of depicting the direction of the boards 11.

The board exchanger 62a as shifter includes a lifter 64a, an arm 65a, and a shiftable support 66a. The lifter 64a has a fork shape and supports the board 11 placed thereon. The arm 65a has one end connected with the lifter 64a, and moves the lifter 64a toward and away from the first movable stage 12a. The shiftable support 66a supports a second end of the arm 65a, and moves in a rotational direction 0 and moves in the direction Z which is perpendicular to the sheet surface of the drawing. The board exchanger 62b as shifter includes a lifter 64b, an arm 65b, and a shiftable support 66b. Those operate in the same manner as the lifter 64a, the arm 65a, and the shiftable support 66a.

A plurality of lifting pins (not shown) are disposed to project from the first and second prealignment adjusters 63a and 63b and the first and second movable stages 12a and 12b for contacting and raising a lower surface of one of the boards 11. The lifters 64a and 64b are inserted between the lifting pins by the board exchangers 62a and 62b to raise the board 11, which is transferred by the lifters 64a and 64b. Specifically, an unexposed one of the boards 11 is picked up from the conveyor 61 by the board exchanger 62a, and is moved to the first prealignment adjuster 63a, which corrects the position of the board 11, before moving the board 11 to the first movable stage 12a. Also, after the exposure to the board 11, the board exchanger 62a shifts the board 11 from the first movable stage 12a to the conveyor 61. The board exchanger 62b operates similarly to the board exchanger 62a.

Each of the first and second prealignment adjusters 63a and 63b includes an image sensor or camera (not shown) and a stage moving mechanism (not shown). The image sensor reads indicia, pattern or the like from the board 11. The stage moving mechanism moves the stage in the directions X, Y and θ. A position of the board 11 is corrected in a preliminary manner for shifting the board 11 to a suitable position on the first and second movable stages 12a and 12b. Also, a turntable 67 is disposed on the second prealignment adjuster 63b for rotationally moving the board 11 in the direction θ after transfer by the board exchanger 62b. Thus, the angle of the board 11 is adjusted. The board 11 on the first movable stage 12a and that on the second movable stage 12b are oriented in the same direction.

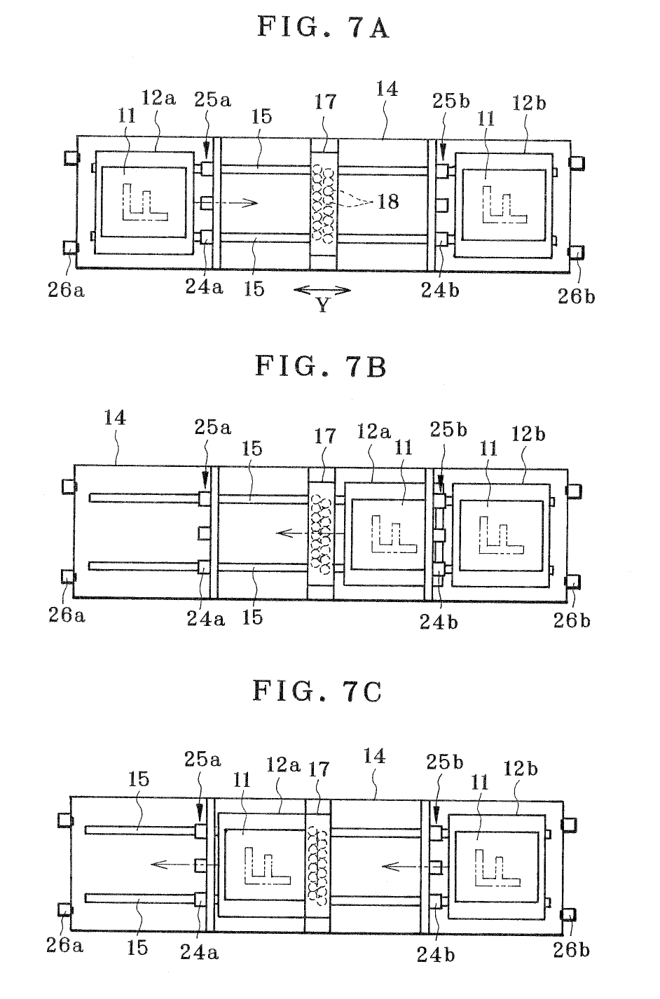

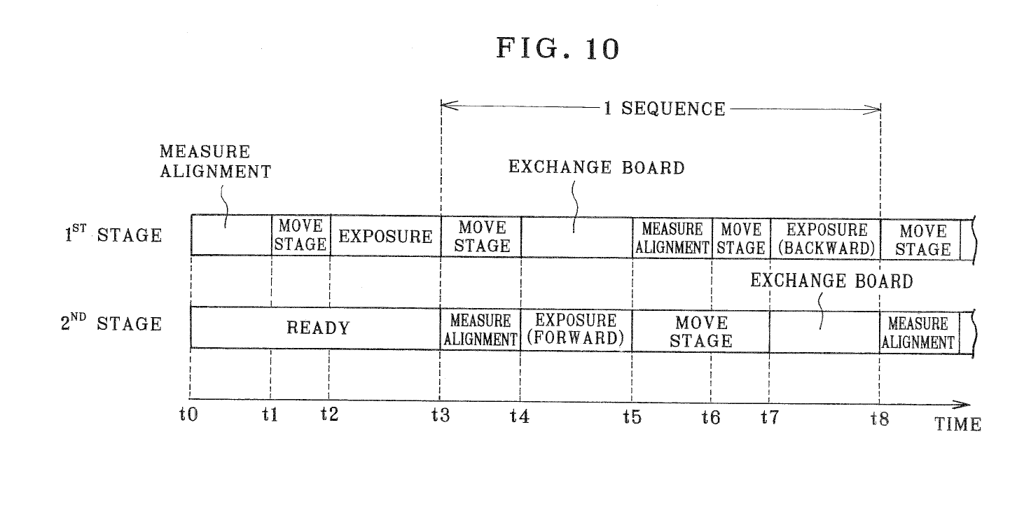

The operation of the digital exposure system 60 is described by reference to a sequence in FIGS. 7A-9 and a timing chart of FIG. 10. At first, the board exchangers 62a and 62b set the boards 11 on the first and second movable stages 12a and 12b as illustrated in FIG. 7A. The boards 11 are oriented in an equal direction. The first movable stage 12a starts moving toward the right to come nearer to the second movable stage 12b, and passes the first board position detector 25a, which measures alignment of the board 11 in the periods t0 and t1 of FIG. 10.

The first movable stage 12a, after passing the first board position detector 25a, moves to pass the multi-beam pattern forming unit 17, and reaches a position near to the second movable stage 12b as illustrated in FIG. 7B in the periods t1 and t2 in FIG. 10. The pattern forming unit 17 does not operate for exposure.

Then the first movable stage 12a moves to the left and away from the second movable stage 12b, to pass the pattern forming unit 17. An exposure is taken by the pattern forming unit 17 on the board 11 on the first movable stage 12a in the periods t2 and t3 of FIG. 10. In FIG. 7C, the first movable stage 12a finishes passing the pattern forming unit 17 to end the exposure. At this time, the second movable stage 12b starts moving to the left to come nearer to the first movable stage 12a. The second movable stage 12b passes the second board position detector 25b, which measures alignment of the board 11 in the periods t3 and t4 of FIG. 10.

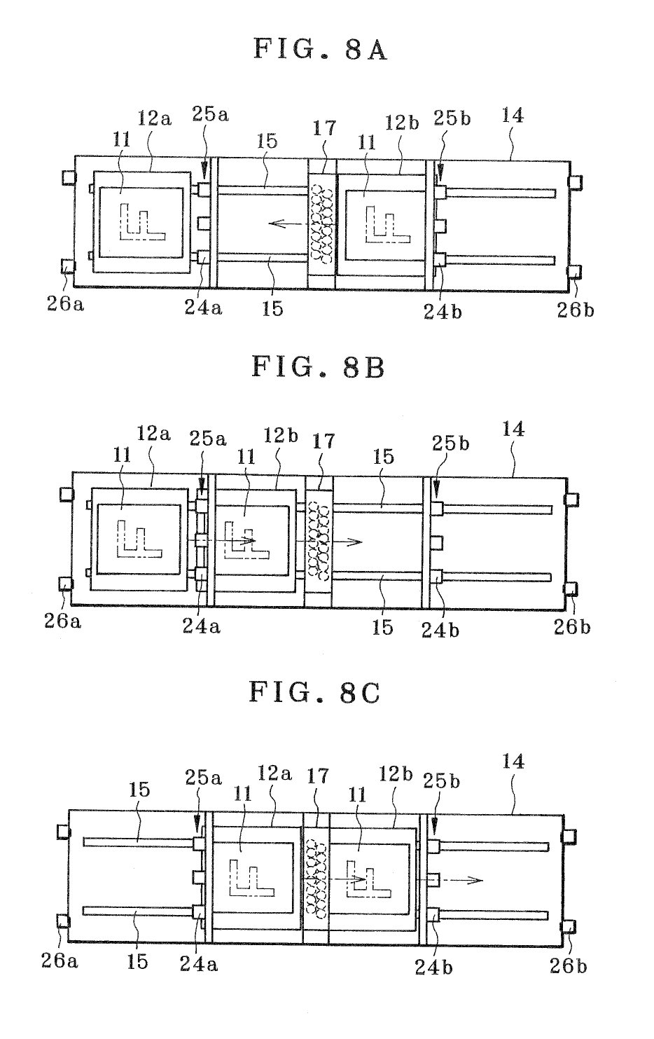

The first movable stage 12a, after passing the pattern forming unit 17, comes to the initial position as illustrated in FIG. 8A. The second movable stage 12b moves to pass the pattern forming unit 17, which takes an exposure to the board 11 on the second movable stage 12b in the periods t4 and t5 of FIG. 10. During the exposure, the board exchanger 62a renews the board 11 on the first movable stage 12a. After the exposure, the second movable stage 12b comes to a position near to the first movable stage 12a as illustrated in FIG. 8B.

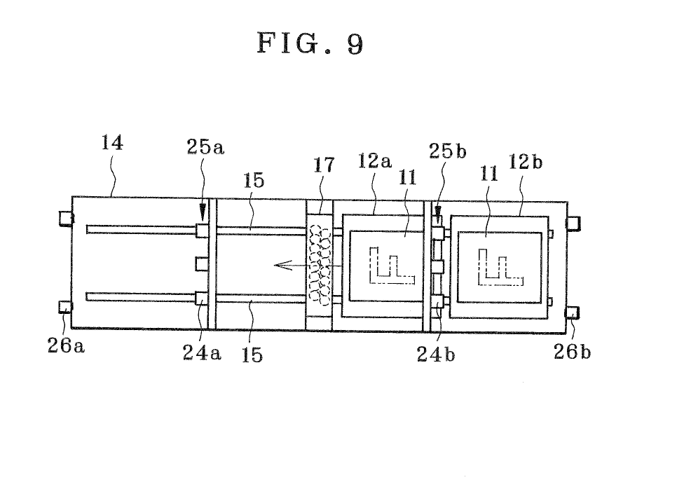

Also, a new one of the boards 11 is placed on the first movable stage 12a, which moves to the right together with the second movable stage 12b. When the first movable stage 12a passes the first board position detector 25a, alignment of the board 11 is measured by the first board position detector 25a in periods t5 and t6 in FIG. 10. In FIG. 8C, the second movable stage 12b passes the pattern forming unit 17 and moves to its initial position. The first movable stage 12a passes the pattern forming unit 17 by following the second movable stage 12b, and comes nearer to the second movable stage 12b in FIG. 9. This is in the periods t6 and t7 in FIG. 10. No exposure is taken by the pattern forming unit 17 for any of the movable stages.

Then the first movable stage 12a moves away from the second movable stage 12b, namely to the left in the drawing, and moves to pass the pattern forming unit 17. The pattern forming unit 17 takes exposure on the board 11 placed on the first movable stage 12a in the periods of t7 and t8 in FIG. 10. During the exposure, the board exchanger 62b renews the board 11 on the second movable stage 12b. After this, a sequence of the periods t3-t8 in FIG. 10 is repeated.

In the digital exposure system 60 of the invention, a second board on the second movable stage can be renewed while a first board on a first movable stage is exposed. Thus, takt time of the digital exposure system 60 can be reduced in comparison with a system having only a single movable stage. Also, the movable stages of the digital exposure system 60 moves in an equal direction to the left for the purpose of taking an exposure. So image data of the same information can be used in each of the exposure periods. The control for the exposure can be equal between the two. No difference occurs in the result of the exposure of the boards, to stabilize the quality of product.

In the embodiment, common pattern data is used between the first and second movable stages. However, pattern data for use with the second movable stage can be different from pattern data for use with the first movable stage.

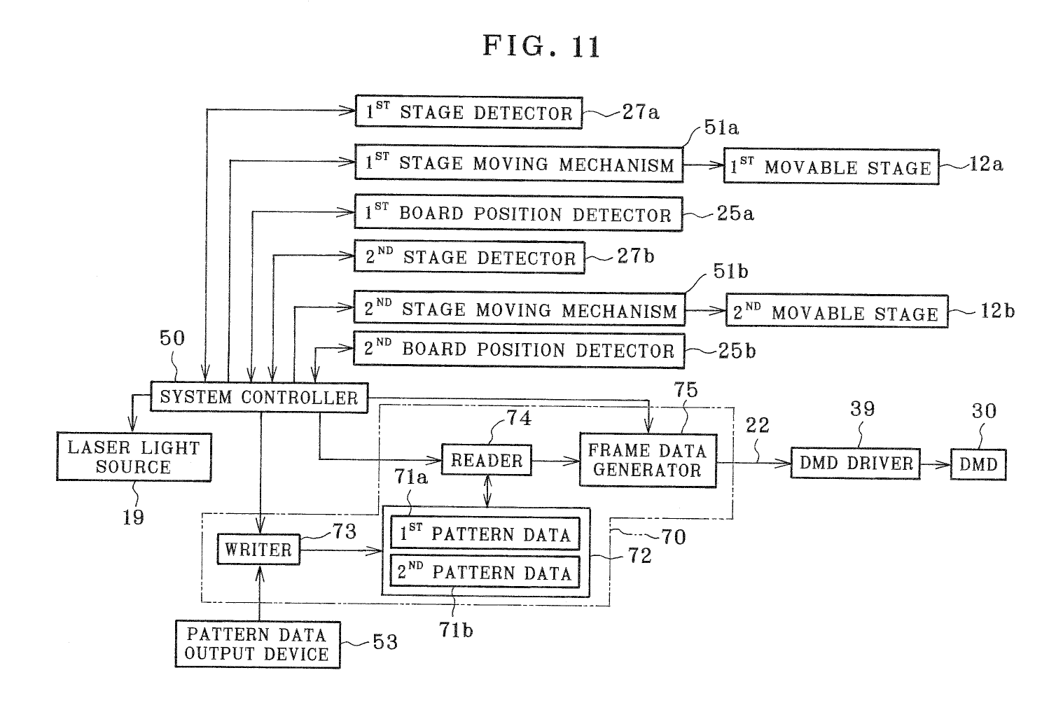

In FIG. 11, one preferred embodiment is illustrated, in which pattern data or image data is different between movable stages. An image processor 70 as pattern data setter has a pattern data storage 72, which stores first pattern data 71a for use in the first movable stage, and second pattern data 71b for use in the second movable stage. A writer 73 is provided with the first and second pattern data 71a and 71b by the pattern data output device 53, and writes those to the pattern data storage 72. A reader 74 is controlled by the system controller 50 to read a selected one of the first and second pattern data 71a and 71b from the pattern data storage 72. Any of the first and second pattern data 71a and 71b is input to a frame data generator 75. The frame data generator 75 creates frame data according to the first pattern data 71a or the second pattern data 71b. The created frame data is input to the DMD driver 39. Note that the pattern data storage 72 can be one storage device having plural memory regions respectively for storing the first and second pattern data 71a and 71b. Also, the pattern data storage 72 may be two storage devices for respectively storing the first and second pattern data 71a and 71b. In the embodiment, the structure of the above embodiment is repeated except for the image processor 70.

In the embodiment, the turntable 67 is positioned on each of the first and second prealignment adjusters 63a and 63b for adjusting a board table to direct boards in one direction. However, a turntable may be placed on a conveyor or the like.

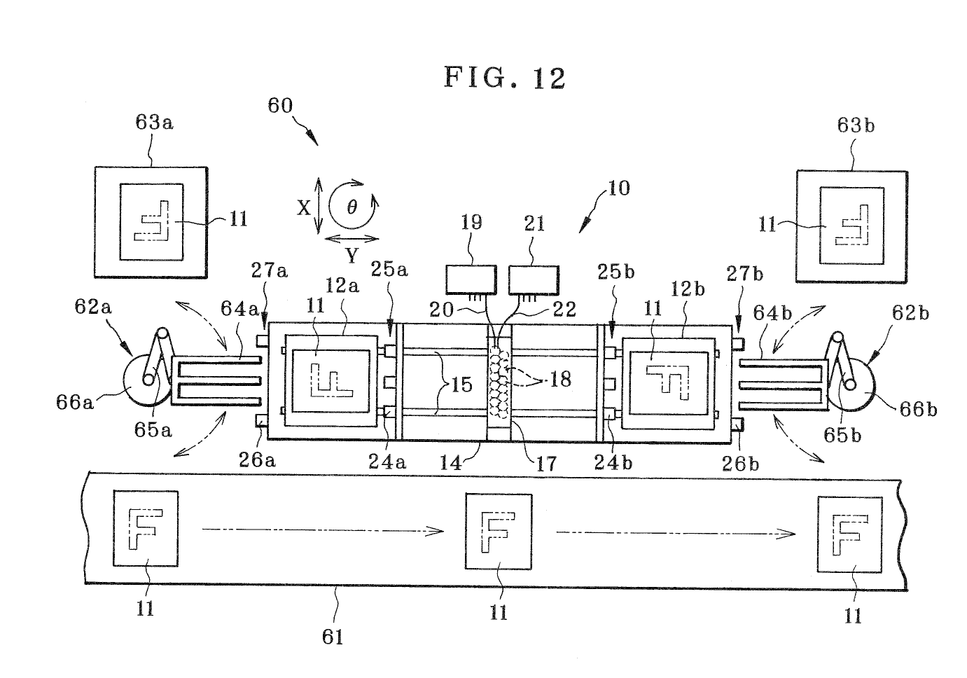

In FIG. 12, another preferred embodiment is illustrated in combination with FIG. 11, in which pattern data are in forms of two opposite directions. In the image processor 70 as pattern data setter, the pattern data storage 72 stores the first pattern data 71a for use in the first movable stage, and second pattern data 71b for use in the second movable stage. Directions of moving of the first and second movable stages 12a and 12b are opposite to one another with a difference of 180 degrees. Should exposures be carried out according to equal image data between the first and second movable stages 12a and 12b, no equal pattern will be created on two boards 11. In consideration of this, the second pattern data 71b is different from the first pattern data 71a. Those are supplied by the pattern data output device 53 for the purpose of resulting in the same exposed pattern between the first and second movable stages 12a and 12b.

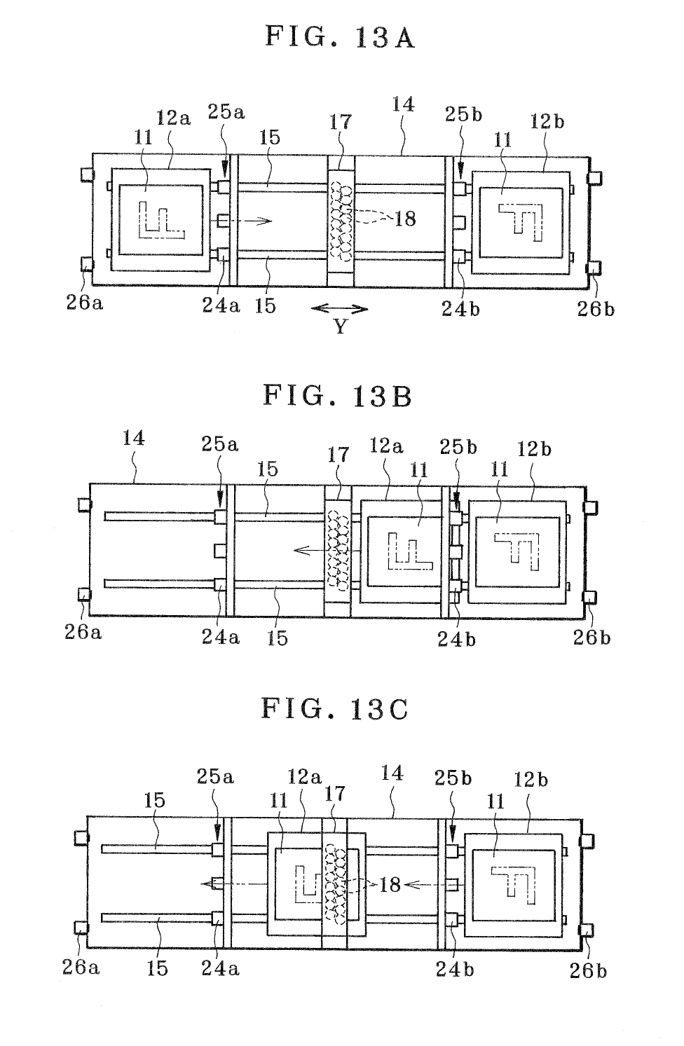

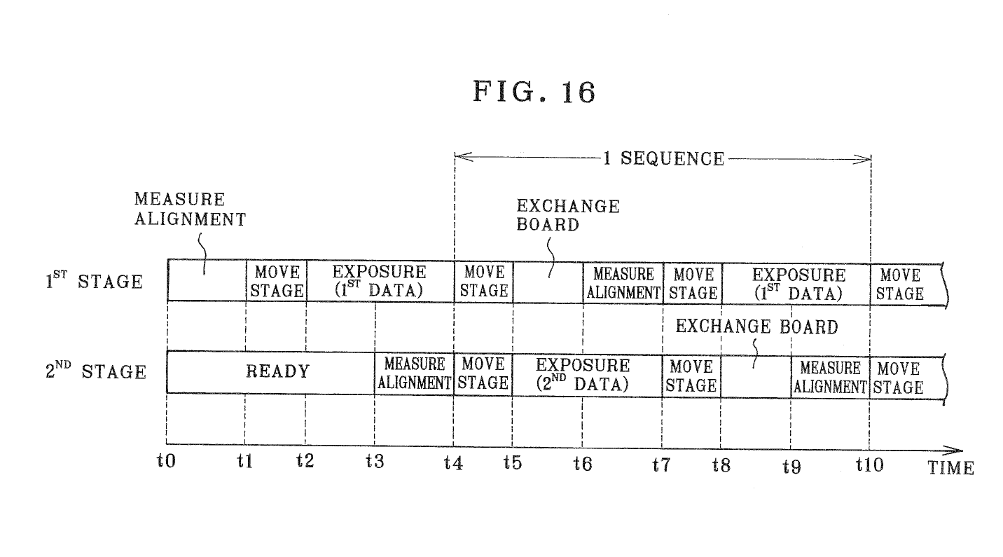

The operation is described with reference to FIG. 16. The sequence related to FIGS. 13A and 13B is the same as that related to FIGS. 7A and 7B. The first movable stage 12a moves to the left and away from the second movable stage 12b. In FIG. 13C, the first movable stage 12a moves to pass the multi-beam pattern forming unit 17, which takes an exposure to the board 11 on the first movable stage 12a according to the first pattern data 71a in the periods t2-t4. During the exposure, the second movable stage 12b moves to the left to come near to the first movable stage 12a, and passes the second board position detector 25b. In the periods t3 and t4 of FIG. 16, the second board position detector 25b measures alignment of the board 11.

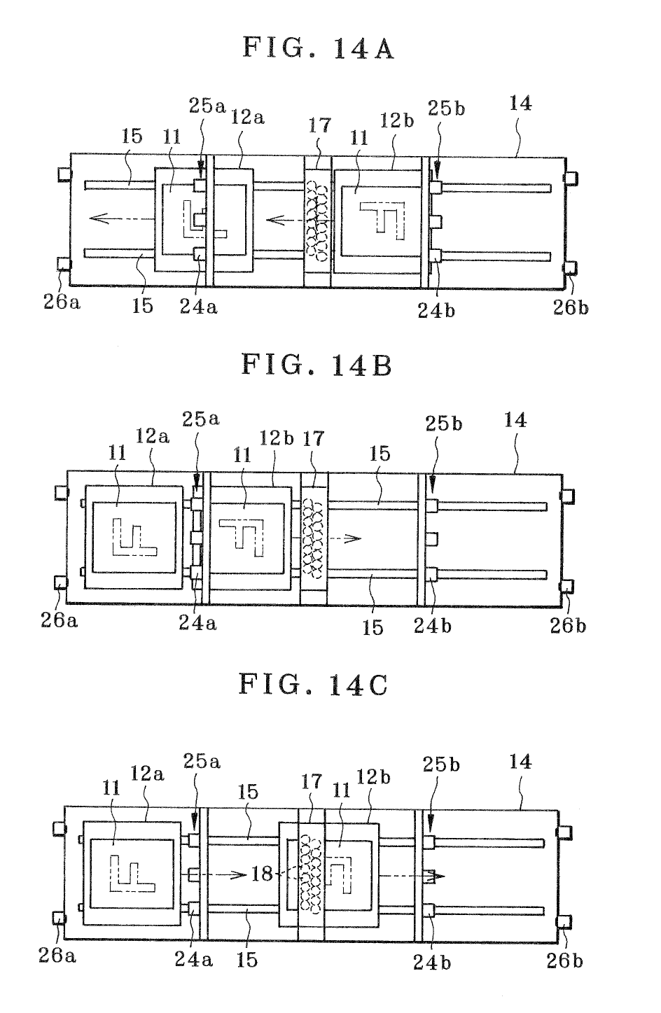

In FIG. 14A, the first movable stage 12a moves to the initial position after passing the pattern forming unit 17 of exposure. The second movable stage 12b passes the pattern forming unit 17, and comes to the position near to the first movable stage 12a as illustrated in FIG. 14B in the periods t4 and t5 of FIG. 16. The pattern forming unit 17 remains inactive in relation to exposure.

Then the second movable stage 12b moves to the right and away from the first movable stage 12a. In FIG. 14C, the second movable stage 12b passes the pattern forming unit 17, which takes an exposure on the board 11 on the second movable stage 12b according to the second pattern data 71b, in periods t5-t7 of FIG. 16. The board exchanger 62a renews the board 11 on the first movable stage 12a in the periods t5 and t6 of FIG. 16. The first movable stage 12a is supplied with a new one of the boards 11, moves to the right to come near to the second movable stage 12b. The first movable stage 12a passes the first board position detector 25a, which measures alignment of the board 11 in periods t6 and t7.

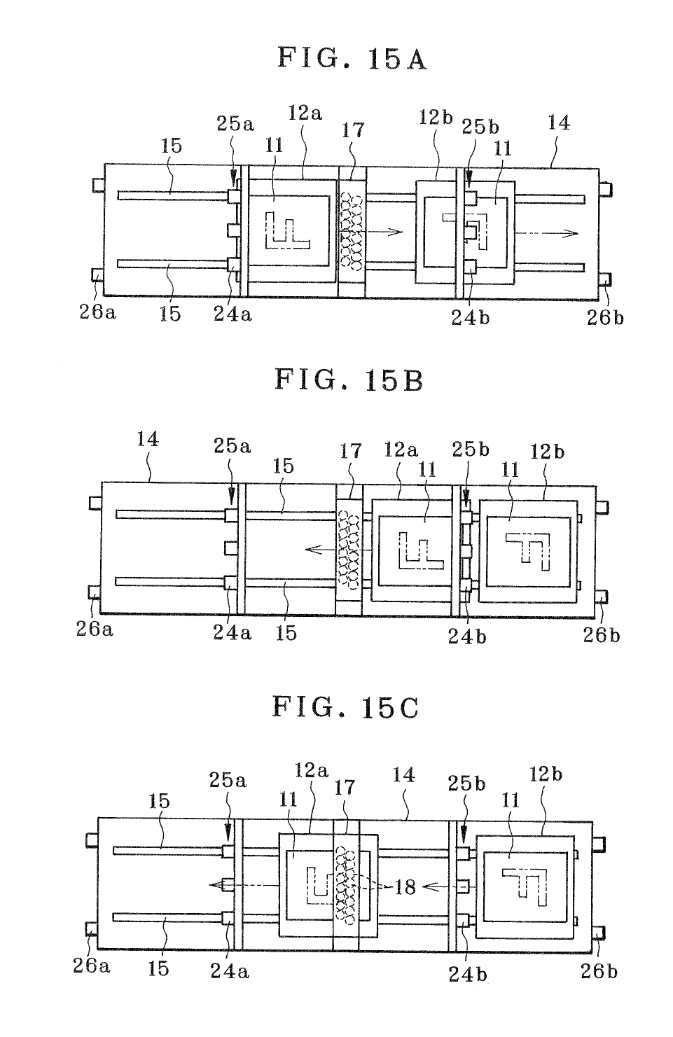

In FIG. 15A, the second movable stage 12b, after passing the pattern forming unit 17 of exposure, moves to the initial position. At this time, the first movable stage 12a passes the pattern forming unit 17 and comes to a position near to the second movable stage 12b as illustrated in FIG. 15B in the periods t7 and t8 of FIG. 16. The pattern forming unit 17 remains inactive for exposure.

Then the first movable stage 12a moves to the left and away from the second movable stage 12b. In FIG. 15C, the first movable stage 12a passes the pattern forming unit 17, which takes an exposure on the board 11 on the first movable stage 12a according to the first pattern data 71a, in periods t8-t10 of FIG. 16. The board exchanger 62b renews the board 11 on the second movable stage 12b in the periods t8 and t9 of FIG. 16. The second movable stage 12b is supplied with a new one of the boards 11, moves to the left to come near to the first movable stage 12a. The second movable stage 12b passes the second board position detector 25b, which measures alignment of the board 11 in periods t9 and t10. After this, a sequence of the periods t4-t10 in FIG. 16 is repeated.

In the digital exposure system 60 of the invention, a second board on the second movable stage can be renewed and with measurement of alignment of the board 11 while a first board on a first movable stage is exposed. Thus, takt time of the digital exposure system 60 can be lowered in comparison with a known system having only a single movable stage.

In the above embodiment of FIGS. 12-16, the board 11 on the second movable stage 12b is rotationally symmetric with that on the first movable stage 12a with an angle of 180 degrees. However, it is possible to orient the board 11 on the second movable stage 12b in the same direction as that on the first movable stage 12a.

In the above embodiments, the first and second movable stages 12a and 12b are moved discretely from one another. However, it is possible to move the first and second movable stages 12a and 12b together.

In the above embodiments, the first and second movable stages 12a and 12b are movable from the pattern forming unit 17 being stationary. However, the first and second movable stages 12a and 12b may be stationary, relative to which the multi-beam pattern forming unit 17 of exposure may be movable. Also, the board position detectors 25a and 25b may be moved at the same time as the pattern forming unit 17. If the first and second movable stages 12a and 12b are movable with the pattern forming unit 17 being stationary, it is possible to measure alignment while the movable stage 12a or 12b is stopped by moving the board position detectors 25a and 25b.

In the above embodiment, the board position detectors 25a and 25b are used. However, a single board position detector may be used, and can be moved for detecting each of plural boards on the stages to measure the alignment.

In the above embodiment, the second pattern data 71b for exposure in the second movable stage 12b is different from the first pattern data 71a for exposure in the first movable stage 12a. However, it is possible to prepare only the first pattern data 71a, and to create second pattern data by inversion of the first pattern data 71a by use of a data inversion circuit.

A pattern forming apparatus of the above embodiments is the digital exposure apparatus 10 for taking an exposure by modulating light beam according to pattern data, such as a photolithographic apparatus. However, a pattern forming apparatus of the invention can be any type of image forming apparatuses, for example ink jet printer, video printer, apparatus of electrophotography, and other electronic apparatuses for image forming according to electronic image data.

Although the present invention has been fully described by way of the preferred embodiments thereof with reference to the accompanying drawings, various changes and modifications will be apparent to those having skill in this field. Therefore, unless otherwise these changes and modifications depart from the scope of the present invention, they should be construed as included therein.

What is claimed is:

1. A pattern forming apparatus comprising:
a pattern forming unit for sequentially forming a pattern on a board passing a pattern forming region according to pattern data;
a moving unit, having a transport path extending to pass said pattern forming region for said board, for transporting first and second boards back and forth in a first direction relative to said pattern forming region and a second direction reverse to said first direction in an alternate manner, said first board being set at one end of a transport path, said second board being set at a remaining end of said transport path;
a controller for controlling said pattern forming unit and said moving unit, for forming said pattern on said first board in a first period of transport in said first direction to pass said pattern forming region, and for forming said pattern on said second board in a second period of transport in said first direction to pass said pattern forming region.

2. A pattern forming apparatus as defined in claim 1, wherein said moving unit includes:
first and second movable stages for respectively supporting said first and second boards placed thereon;
a guide mechanism for movably guiding said first and second movable stages on said transport path;
a moving mechanism for moving said first and second movable stages discretely from one another on said transport path.

3. A pattern forming apparatus as defined in claim 2, further comprising:
a board position detector for detecting a position offset value of said board with reference to a suitable position; and
a pattern data corrector for correcting said pattern data according to said position offset value from said board position detector.

4. A pattern forming apparatus as defined in claim 3, wherein said moving unit, during or after said first period, moves said second board toward said pattern forming unit in said first direction, to measure said second board in said board position detector;
said moving unit, during or after said second period, moves said first board toward said pattern forming unit in said second direction, to measure said first board in said board position detector.

5. A pattern forming apparatus as defined in claim 2, further comprising first and second board exchangers disposed at said ends of said transport path, said first board exchanger renewing said first board in said second period, and said second board exchanger renewing said second board in said first period.

6. A pattern forming apparatus as defined in claim 5, wherein a set of said first and second board exchangers includes:
a conveyor, disposed to extend along said transport path, for setting said board near to said first movable stage at said one end of said transport path and near to said second movable stage at said remaining end of said transport path;
first and second shifters for holding said board from said conveyor and for placing said board on respectively said first and second movable stages.

7. A pattern forming apparatus as defined in claim 6, further comprising first and second prealignment adjusters for position adjustment of said board by supporting said board from said first and second shifters.

8. A pattern forming apparatus as defined in claim 7, wherein said second prealignment adjuster has a turntable for changing an orientation of said board rotationally by a half rotation.

9. A pattern forming apparatus as defined in claim 2, further comprising an angle adjuster for adjusting an angle of said board relative to said transport path, to orient said board in a predetermined direction.

10. A pattern forming apparatus as defined in claim 2, further comprising a pattern data setter for setting said pattern data in a different manner between said first and second periods.

11. A pattern forming apparatus as defined in claim 2, wherein said board is photosensitive;
said pattern forming unit includes:
a light source for emitting light; and
a light valve for modulating said light according to said pattern data, and for exposing said pattern by applying said light to said board.

12. A pattern forming apparatus as defined in claim 11, wherein said light valve is constituted by plural light valves, said pattern forming unit is a multi-beam type, and said light is laser light.

13. A pattern forming apparatus as defined in claim 11, wherein said light valve includes a spatial light modulator.

14. A pattern forming method of forming a pattern on a moving board according to pattern data, comprising steps of:
setting a first board at one end of a transport path and a second board at a remaining end of said transport path which extends to pass a pattern forming region, said first and second boards being movable back and forth in a first direction relative to said pattern forming region and a second direction reverse to said first direction in an alternate manner;
forming said pattern on said first board in a first period of transport in said first direction to pass said pattern forming region;
forming said pattern on said second board in a second period of transport in said first direction to pass said pattern forming region.

15. A pattern forming apparatus comprising:
a pattern forming unit for sequentially forming a pattern on a board passing a pattern forming region according to pattern data;
a moving unit, having a transport path extending to pass said pattern forming region for said board, for transporting first and second boards back and forth in a first direction relative to said pattern forming region and a second direction reverse to said first direction in an alternate manner, said first board being set at one end of a transport path, said second board being set at a remaining end of said transport path;
a controller for controlling said pattern forming unit and said moving unit, for forming said pattern on said first board in a first period of transport in said first direction to pass said pattern forming region, and for forming said pattern on said second board in a second period of transport in said second direction to pass said pattern forming region; and
a pattern data setter for setting said pattern data different between said first and second periods.

16. A pattern forming apparatus as defined in claim 15, wherein said moving unit includes:
first and second movable stages for respectively supporting said first and second boards placed thereon;
a guide mechanism for movably guiding said first and second movable stages on said transport path;
a moving mechanism for moving said first and second movable stages discretely from one another on said transport path.

17. A pattern forming apparatus as defined in claim 16, wherein said pattern data setter sets said pattern data in a different manner between said first and second periods so as to form said pattern being equal on said boards in said first and second periods.

18. A pattern forming apparatus as defined in claim 16, further comprising:
a board position detector for detecting a position offset value of said board with reference to a suitable position; and
a pattern data corrector for correcting said pattern data according to said position offset value from said board position detector.

19. A pattern forming apparatus as defined in claim 18, wherein said moving unit, during or after said first period, moves said second board toward said pattern forming unit in said first direction, to measure said second board in said board position detector;
said moving unit, during or after said second period, moves said first board toward said pattern forming unit in said second direction, to measure said first board in said board position detector.

20. A pattern forming apparatus as defined in claim 16, wherein while said pattern forming unit carries out said pattern forming on said first board among said plural boards, said board position detector detects said position offset value of said second board among said plural boards.

21. A pattern forming apparatus as defined in claim 16, further comprising first and second board exchangers disposed at said ends of said transport path, said first board exchanger renewing said first board in said second period, and said second board exchanger renewing said second board in said first period.

22. A pattern forming apparatus as defined in claim 21, wherein a set of said first and second board exchangers includes:
a conveyor, disposed to extend along said transport path, for setting said board near to said first movable stage at said one end of said transport path and near to said second movable stage at said remaining end of said transport path;
first and second shifters for holding said board from said conveyor and for placing said board on respectively said first and second movable stages.

23. A pattern forming method of forming a pattern on a moving board according to pattern data, comprising steps of:
setting a first board at one end of a transport path and a second board at a remaining end of said transport path which extends to pass a pattern forming region, said first and second boards being movable back and forth in a first direction relative to said pattern forming region and a second direction reverse to said first direction in an alternate manner;
forming said pattern on said first board in a first period of transport in said first direction to pass said pattern forming region;
forming said pattern on said second board in a second period of transport in said second direction to pass said pattern forming region;
wherein said pattern data is set different between said first and second periods.
